(19) United States
(12) Patent Application Publication
(10) Pub. No.: US 2017/0028571 A1
(43) Pub. Date: Feb. 2, 2017

(54) KNIFE AND BLADE FINISHING METHOD

(71) Applicant: IHI Corporation, Koto-ku (JP)

(72) Inventors: Yoshiyuki SAITO, Tokyo (JP); Hiroyuki OCHIAI, Tokyo (JP)

(73) Assignee: IHI Corporation, Koto-ku (JP)

(21) Appl. No.: 15/291,321

(22) Filed: Oct. 12, 2016

Related U.S. Application Data
(63) Continuation of application No. PCT/JP2015/071671, filed on Jul. 30, 2015.

(30) Foreign Application Priority Data
Sep. 1, 2014 (JP) 2014-176754

(51) Int. Cl. B26B 9/00; B24C 1/06; C23C 14/06; C23C 16/30; C23C 14/22; B26B 3/02; C23C 16/27

(52) U.S. Cl. CPC B26B 9/00; B26B 3/02; B24C 1/06; C23C 16/27; C23C 16/30; C23C 14/22; C23C 14/0611

(57) ABSTRACT

A first cutting blade 5 is formed on a blade edge portion 3a on one side in a blade thickness direction of a blade 3, a second cutting blade 7 is formed on a blade edge portion on other side in the blade thickness direction of the blade 3, a handle 9 is provided on the blade 3, a hard coating 11 if formed by PVD or CVD on the blade edge portion 3b on the other side in the blade thickness direction of the blade 3, a rough surface 13 is formed by grinding processing or shot blast processing on a base of the hard coating 11 on the blade edge portion 3b on the other side in the blade thickness direction of the blade 3, and a maximum height Rz of surface roughness of the rough surface 13 is set to 10 to 30 μm.

### CROSS REFERENCE TO RELATED APPLICATIONS

This application is a continuation application of international application No. PCT/JP2015/071671 filed Jul. 30, 2015, which claims priority to Japanese Patent Application No. 2014-176754 filed Sep. 1, 2014, each of which is hereby incorporated by reference in their entity.

### BACKGROUND

1. Technical Field

The present disclosure relates to a knife such as a double-edged kitchen knife, a single-edged kitchen knife and a double-edged knife, and to a method for finishing a blade for use in the knife.

2. Description of Related Art

In recent years, a variety of developments have been made for the purpose of enhancing durability and sharpness of a kitchen knife, and as related arts of the kitchen knife, there are those described in Patent Document 1 and Patent Document 2. Then, features of the first related art (kitchen knife described in Patent Document 1) and the second related art (kitchen knife described in Patent Document 2) are as follows.

In the first related art, a hard coating is formed by PVD (physical vapor deposition) on substantially an entire surface of a blade including a one-side blade edge portion in a blade thickness direction of the blade. In such a way, mechanical strength (hardness) of a blade of the kitchen knife is enhanced, and abrasion of the blade of the kitchen knife is reduced, whereby the durability of the kitchen knife can be enhanced sufficiently.

In the second related art, on a one-side blade edge portion in a blade thickness direction of a blade, a hard coating with irregularities is formed by discharge surface treatment. In such a way, mechanical strength of the blade of the kitchen knife is enhanced, and abrasion of the blade of the kitchen knife is reduced, whereby the durability of the kitchen knife is enhanced sufficiently, and in addition, the blade of the kitchen knife is allowed to exhibit a saw tooth-like irregular line (line with irregularities), whereby the sharpness of the kitchen knife can be enhanced sufficiently. Note that the second related art is developed by the inventors of this application.

### RELATED ART DOCUMENT

Patent Document 1: JP H10-36966 A

Patent Document 2: JP 2008-264116 A

### SUMMARY

Meanwhile, in the first related art, though the durability of the kitchen knife can be enhanced sufficiently, the blade of the kitchen knife exhibits a flat line, in other words, a line without irregularities, and accordingly, there is a problem that the sharpness of the kitchen knife cannot be enhanced sufficiently. Meanwhile, in the second related art, though the durability and sharpness of the kitchen knife can be enhanced sufficiently, the discharge surface treatment cannot be performed in a batch unit (batch processing cannot be performed therefor) unlike the PVD, in other words, such hard coatings cannot be formed on a large number of blades at one time, and there is a problem that productivity of the kitchen knife cannot be enhanced sufficiently. That is to say, in the first related art and the second related art, there is a problem that it is difficult to enhance the durability and sharpness of the kitchen knife sufficiently while enhancing the productivity of the kitchen knife sufficiently.

Note that the above-mentioned problem occurs not only in the kitchen knife but also in other knives in a similar way.

In this connection, it is an object of the present disclosure to provide a knife having a novel configuration and a novel blade finishing method, each of which is capable of solving the above-mentioned problems.

In order to solve the above-mentioned problems, the inventors of this application experimentally made a variety of kitchen knives, in each of which a cutting blade is formed on a blade edge portion at least on one side in a blade thickness direction, and conducted a test of sharpness for those kitchen knives. As a result, the inventors were able to obtain novel knowledge that, in a case of forming a hard coating by PVD or CVD on a blade edge portion at least on other side in the blade thickness direction of the blade, an appropriate rough surface (fine irregular surface) is formed in advance on a base of the hard coating on the blade edge portion on the other side in the blade thickness direction of the blade, whereby the blade of the kitchen knife (knife) can be allowed to exhibit a saw tooth-like irregular line (line with irregularities). Then, the inventors have achieved completion of the present disclosure. Here, the “appropriate rough surface” refers to a rough surface in which a maximum height (Rz) of surface roughness is set to 10 to 30 μm.

A first feature of the present disclosure is summarized to be a knife, which includes: a blade in which a cutting blade is formed on a blade edge portion at least on one side in a blade thickness direction; and a handle provided on the blade, wherein a hard coating is formed by PVD (physical vapor deposition) or CVD (chemical vapor deposition) on a blade edge portion at least on other side in the blade thickness direction of the blade, a rough surface (fine irregular surface) is formed on a base of the hard coating in the blade edge portion on the other side in the blade thickness direction of the blade, and a maximum height of surface roughness of the rough surface is set to 10 to 30 μm.

Note that in the description of this application and the scope of claims thereof, the “knife” implies a double-edged kitchen knife, a single-edged kitchen knife, a double-edged knife, a single-edged knife and the like.

In accordance with the first feature, the hard coating is formed on the blade edge portion at least on the other side in the blade thickness direction of the blade, and accordingly, mechanical strength (hardness) of such a blade edge of the knife can be enhanced. Moreover, the PVD or the CVD is used as a forming method of the hard coating, and accordingly, such hard coatings can be formed on a large number of the blades at one time by batch processing.

The hard coating is formed by the PVD or the CVD on the blade edge portion at least on the other side in the blade thickness direction of the blade, and thereafter, the rough surface is formed on the base of the hard coating in the blade edge portion on the other side in the blade thickness direction of the blade, and the maximum height (Rz) of the surface roughness of the rough surface is set to 10 to 30 μm. Accordingly, when the above-mentioned novel knowledge is applied, the blade edge of the knife can be allowed to exhibit a saw tooth-like irregular line (line with irregularities).

A second feature of the present disclosure is summarized to be a blade finishing method for finishing a blade, which is used for a knife and has a cutting blade formed on a blade edge portion at least on one side in a blade thickness direction, the blade finishing method including: a rough surface forming step (irregular surface forming step) of forming a rough surface (fine irregular surface), in which a maximum height of surface roughness is set to 10 to 30 μm, on a blade edge portion at least on other side in the blade thickness direction of the blade; and a coating forming step of, after the rough surface forming step is ended, forming a hard coating by PVD (physical vapor deposition) or CVD (chemical vapor deposition) on the blade edge portion at least on the other side in the blade thickness direction of the blade so as to cover the rough surface.

In accordance with the second feature, the hard coating is formed on the blade edge portion at least on the other side in the blade thickness direction of the blade, and accordingly, the mechanical strength (hardness) of the blade edge of the knife can be enhanced. Moreover, the PVD or the CVD is used as the forming method of the hard coating, and accordingly, the hard coatings can be formed on a large number of the blades at one time by batch processing.

The rough surface, in which the maximum height of the surface roughness is set to 10 to 30 μm, is formed on the blade edge portion at least on the other side in the blade thickness direction of the blade, and the hard coating is formed by the PVD or the CVD on the blade edge portion on the other side in the blade thickness direction of the blade so as to cover the rough surface. Accordingly, when the above-mentioned novel knowledge is applied, the blade edge of the knife can be allowed to exhibit the saw tooth-like irregular line (line with irregularities).

In accordance with the present disclosure, the mechanical strength (hardness) of the blade edge of the knife can be enhanced, and accordingly, the abrasion of the blade edge of the knife is reduced, and the durability of the knife can be enhanced sufficiently. Moreover, the hard coatings can be formed on a large number of the blades at one time by the batch processing, and accordingly, the productivity of the knife can be enhanced sufficiently. Furthermore, the blade tip of the knife exhibits the irregular line, and accordingly, the sharpness of the knife can be enhanced sufficiently. That is to say, in accordance with the present disclosure, the durability and sharpness of the knife can be enhanced sufficiently while enhancing the productivity of the knife sufficiently.

### BRIEF DESCRIPTION OF DRAWINGS

FIG. 1A is a view showing a double-edged kitchen knife according to a first embodiment of the present disclosure, FIG. 1B is a partial enlarged view of a blade periphery including a blade of the double-edged kitchen knife according to the first embodiment of the present disclosure, and FIG. 1C is an enlarged cross-sectional view taken along a line IC-IC in FIG. 1A.

FIG. 2 is a schematic view explaining a rough surface forming step in a blade finishing method according to a second embodiment of the present disclosure.

FIG. 3 is a schematic view explaining a thin film forming step in the blade finishing method according to the second embodiment of the present disclosure.

FIG. 4 is a schematic view explaining an edging step in the blade finishing method according to the second embodiment of the present disclosure.

FIG. 5A is a view showing a single-edged kitchen knife according to a third embodiment of the present disclosure, FIG. 5B is a partial enlarged view of a blade periphery including a blade of the single-edged kitchen knife according to the third embodiment of the present disclosure, and FIG. 5C is an enlarged cross-sectional view taken along a line VC-VC in FIG. 5A.

### DETAILED DESCRIPTION OF EMBODIMENTS

A description is made of embodiments (first embodiment, second embodiment, third embodiment) of the present disclosure with reference to the drawings. Note that, in the drawings, “D” denotes a blade thickness direction, “D1” denotes one side in the blade thickness direction, and “D2” denotes other side in the blade thickness direction.

### First Embodiment

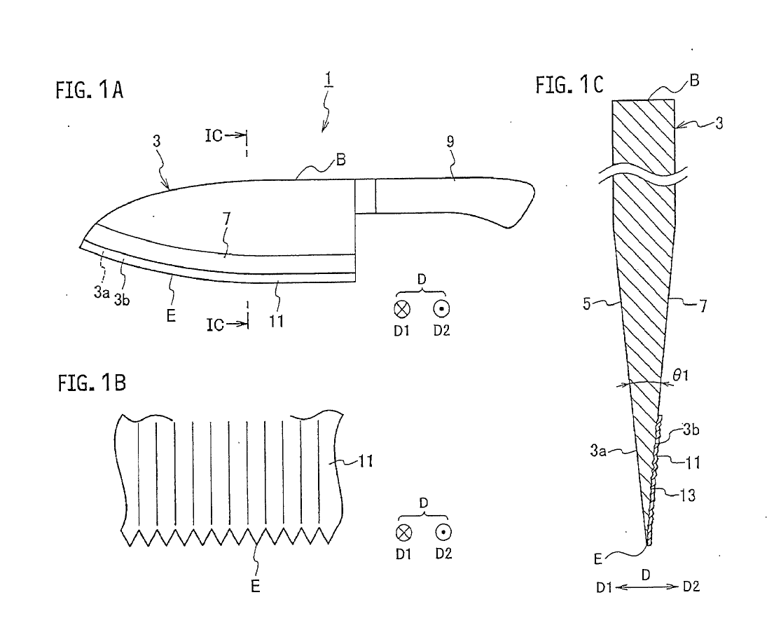

As shown in FIGS. 1A, 1B and 1C, a double-edged kitchen knife 1 according to the first embodiment of the present disclosure includes a blade (kitchen knife body) 3, and this blade 3 is made of stainless steel or steel, which is excellent in rust resistance. Moreover, on a blade edge portion (edge portion of a blade edge E) 3a on one side in the blade thickness direction of the blade 3, a first cutting blade 5 is formed, and on a blade edge portion 3b on other side in the blade thickness direction of the blade 3, a second cutting blade 7 is formed. Furthermore, on a base end side of a back B of the blade 3, a handle 9 to be gripped by hand is provided, and this handle 9 is made of plastics or a piece of plywood.

On the blade edge portion 3b (edge portion of the second cutting blade 7) on the other side in the blade thickness direction of the blade 3, a hard coating 11 is formed, for example, by ion plating, and this hard coating 11 is made of: ceramics such as titanium carbide (TiC) and titanium aluminite ride (TiALN); or a carbon material such as diamond-like carbon. Note that, as a forming method (coating method) of the hard coating 11, other PVD (physical vapor deposition) such as vacuum evaporation and sputtering or CVD (chemical vapor deposition) such as plasma CVD, thermal CVD and photo CVD may be used in place of using the ion plating. The hard coating 11 may be formed on substantially an entire surface of the blade 3 including the second cutting blade 7 of the blade 3.

On a base of the hard coating 11 on the blade edge portion 3b on the other side in the blade thickness direction of the blade 3, a rough surface (fine irregular surface) 13 is formed by grinding processing, shot blast processing or the like. Moreover, a maximum height (Rz) of surface roughness of the rough surface 13 is set to 10 to 30 μm. A reason why the maximum height (Rz) of the surface roughness of the rough surface 13 is set within the above-described range is because, by a test of the sharpness by the inventors of this application, it is confirmed that the sharpness of the double-edged kitchen knife 1 decreases if the maximum height (Rz) is out of this range.

A blade angle (angle on edge E side) θ1 of the blade 3 is set to 10 to 20 degrees, or 10 to 15 degrees. A reason why the blade angle θ1 of the blade 3 is limited to the above-described range is in order to maintain a good sharpness state of the double-edged kitchen knife 1 while sufficiently ensuring rigidity on the blade edge E side of the blade 3. Moreover, the blade edge portion 3a on one side in the blade thickness direction of the blade 3 is subjected to edging processing. As a result of the edging, the hard coating is removed from the blade edge portion 3a on one side.

Subsequently, a description is made of functions and effects of the first embodiment of the present disclosure.

The hard coating 11 is formed on the second cutting blade 7 of the blade 3, and accordingly, mechanical strength (hardness) of the blade edge E of the double-edged kitchen knife 1 can be enhanced. Moreover, the PVD or the CVD is used as a forming method of the hard coating 11, and accordingly, such hard coatings 11 can be formed on a large number of the blades 3 at one time by the batch processing.

The hard coating 11 is formed on the second cutting blade 7 of the blade 3 by the PVD or the CVD, and thereafter, the rough surface 13 is formed on the base of the hard coating 11 on the second cutting blade 7 of the blade 3, and the maximum height (Rz) of the surface roughness of the rough surface 13 is set to 10 to 30 μm. Accordingly, when the above-mentioned novel knowledge is applied, then as shown in FIG. 1B, the blade edge E of the double-edged kitchen knife 1 can be allowed to exhibit the saw tooth-like irregular line (line with irregularities).

Hence, in accordance with the first embodiment of the present disclosure, the mechanical strength of the blade edge E of the double-edged kitchen knife 1 can be enhanced, and accordingly, the abrasion of the blade edge E of the double-edged kitchen knife 1 is reduced, and the durability of the double-edged kitchen knife 1 can be enhanced sufficiently. The hard coating is not present on the surface ground for the edging, and accordingly, this surface is abraded first, whereby the surface added with the hard coating having irregularities appears on the blade. Accordingly, on the blade, a hard blade with a small saw shape is reproduced. Therefore, the sharpness is less likely to decrease. Such hard coatings 11 can be formed on a large number of the blades 3 at one time by the batch processing, and accordingly, the productivity of the double-edged kitchen knife 1 can be enhanced sufficiently. Moreover, the blade edge E of the double-edged kitchen knife 1 exhibits the saw tooth-like irregular line, and accordingly, the sharpness of the double-edged kitchen knife 1 can be enhanced sufficiently. That is to say, in accordance with the first embodiment of the present disclosure, the durability and sharpness of the double-edged kitchen knife 1 can be enhanced sufficiently while enhancing the productivity of the double-edged kitchen knife 1 sufficiently.

Note that, by the test of the sharpness by the inventors of this application, it is confirmed that, since the double-edged kitchen knife 1 has small irregularities with a saw shape, good sharpness of the double-edged kitchen knife 1 is maintained even in a case where the sharpness of the blade edge E of the double-edged kitchen knife 1 decreases owing to the abrasion of the blade edge E of the double-edged kitchen knife 1.

### Second Embodiment

A blade finishing method according to the second embodiment of the present disclosure is a method for finishing a large number of the blades 3 for use in the double-edged kitchen knife 1 according to the first embodiment of the present disclosure, and the blade finishing method includes: (i) a rough surface forming step (irregular surface forming step); (ii) a coating forming step; and (iii) an edging step. Then, specific contents of the respective steps in the blade finishing method according to the second embodiment of the present disclosure are as follows.

(i) Rough Surface Forming Step

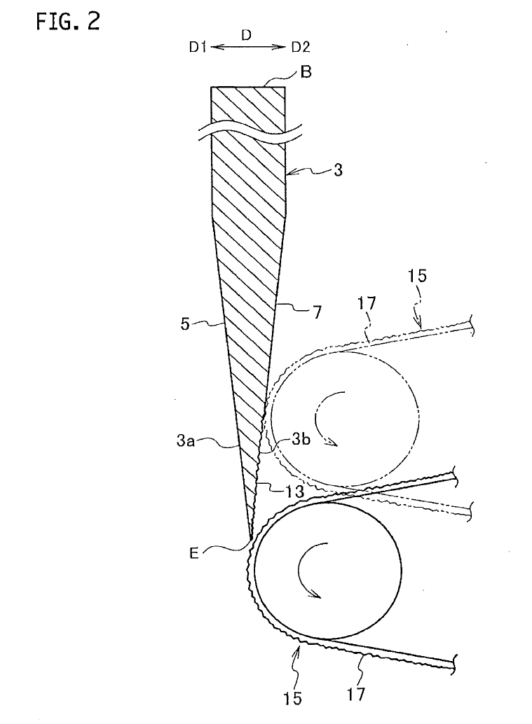

As shown in FIG. 2, a belt grinding machine 15 is used, and in a state where a belt 17 of the belt grinding machine 15 is run circularly, the grinding processing is implemented for the blade edge portion 3b on the other side in the blade thickness direction of each blade 3 while moving the belt grinding machine 15 relatively to each blade 3 from the blade edge E of each blade 3 toward the back B side thereof. In such a way, the rough surface 13, in which the maximum height (Rz) of the surface roughness is set to 10 to 30 μm, can be formed on the blade edge portion 3b on the other side in the blade thickness direction of each blade 3. A reason why the maximum height (Rz) of the surface roughness of the rough surface 13 is set to 10 to 30 μm is the same as mentioned above. Note that, in place of the grinding processing, the shot blast processing or the like may be performed for the blade edge portion 3b on the other side in the blade thickness direction of each blade 3.

(ii) Coating Forming Step

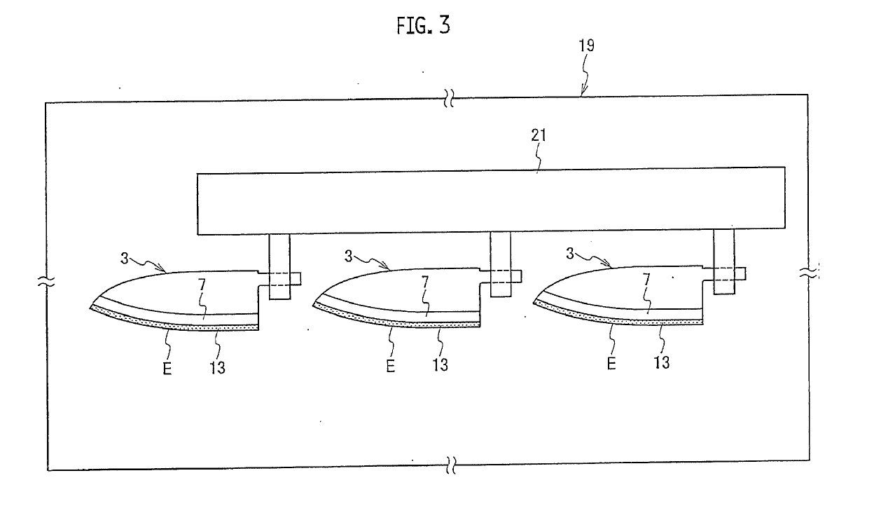

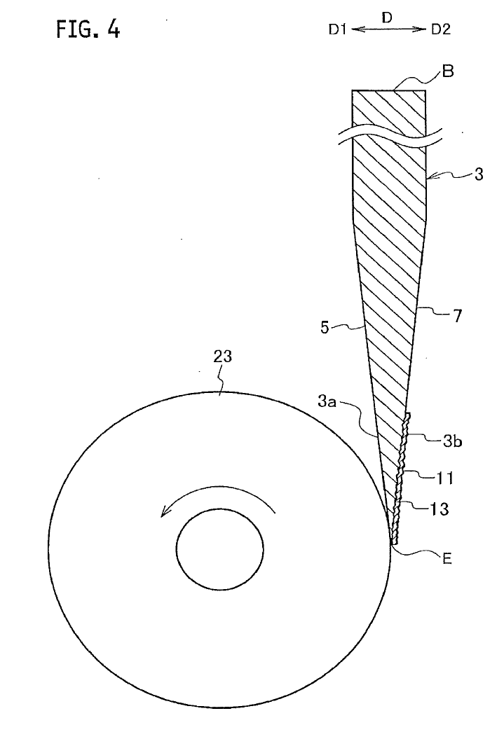

After the rough surface forming step is ended, as shown in FIG. 3, a large number of the blades 3 (only the blades 3 as heads of plural lines are shown) are set in a state of being arrayed in the respective lines on a jig 21 installed in a treatment vessel (treatment furnace) 19, and in addition, masking is performed appropriately for portions of the respective blades 3, which are other than the second cutting blades 7. Then, while keeping an inside of the treatment vessel 19 in a vacuum atmosphere, the hard coating 11 (refer to FIG. 1C and FIG. 4) made of the ceramics or the carbon material is formed by the ion plating on the blade edge portion 3b (edge portion of the second cutting blade 7) on the other side in the blade thickness direction of each blade 3 so as to cover the rough surface 13. Note that a specific content of the ion plating is omitted since the specific content is known in public. As the forming method of the hard coating 11, the other PVD (physical vapor deposition) such as vacuum evaporation and sputtering or the CVD (chemical vapor deposition) such as plasma CVD, thermal CVD and photo CVD may be used in place of using the ion plating. The masking for each blade 3 may be omitted, and the hard coating 11 may be formed on substantially the entire surface of the blade 3 including the second cutting blade 7 of each blade 3.

(iii) Edging Step

After the coating forming step is ended, as shown in FIG. 4, a rotating grindstone 23 is used, and the rotating grindstone 23 is allowed to relatively approach each blade 3 in a state of being rotated about an axial center (axial center of the rotating grindstone 23) thereof, and then grinds the blade edge portion 3a on one side in the blade thickness direction of each blade 3, in other words, grinds a surface of the blade edge portion 3a that does not have rough irregularities, whereby the edging processing is performed. Since the blade includes the hard coating with irregularities, it is recommended to use a diamond grindstone. In such a way, the blade edge E of each blade 3 can be sharpened.

Subsequently, a description is made of functions and effects of the second embodiment of the present disclosure.

The hard coating 11 is formed on the second cutting blade 7 of the blade 3, and accordingly, the mechanical strength (hardness) of the blade edge E of the double-edged kitchen knife 1 can be enhanced. Moreover, the PVD or the CVD is used as the forming method of the hard coating 11, and accordingly, such hard coatings 11 can be formed on a large number of the blades 3 at one time by the batch processing.

The rough surface 13, in which the maximum height of the surface roughness is set to 10 to 30 μm, is formed on the second cutting blade 7 of the blade 3, and the hard coating 11 is formed by the PVD or the CVD on the blade edge portion 3b on the other side in the blade thickness direction of each blade 3 so as to cover the rough surface 13. Accordingly, when the above-mentioned novel knowledge is applied, then as shown in FIG. 1B, the blade edge E of the double-edged kitchen knife 1 can be allowed to exhibit the saw tooth-like irregular line (line with irregularities).

Hence, also in the second embodiment of the present disclosure, similar effects to those of the first embodiment of the present disclosure are exerted.

### Third Embodiment

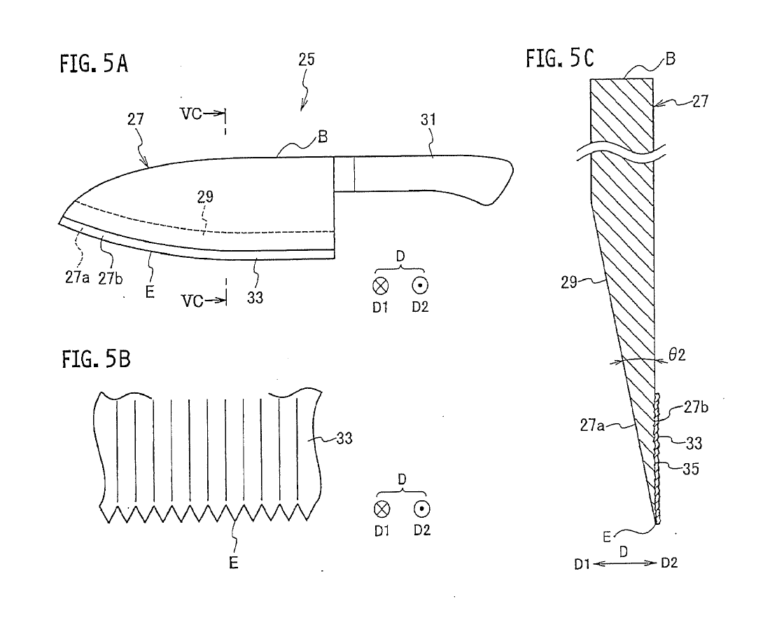

As shown in FIGS. 5A, 5B and 5C, a single-edged kitchen knife 25 according to the third embodiment of the present disclosure includes a blade (kitchen knife body) 27, and this blade 27 is made of stainless steel or steel, which is excellent in rust resistance. Moreover, a cutting blade 29 is formed only on a blade edge portion (edge portion of a blade edge E) on one side in a blade thickness direction of the blade 27. Furthermore, on a base end side of a back B of the blade 27, a handle 31 to be gripped by hand is provided, and this handle 31 is made of plastics or a piece of plywood.

In a similar way to the double-edged kitchen knife 1 (refer to FIGS. 1A and 1C) according to the first embodiment of the present disclosure, on a blade edge portion 27b on other side in the blade thickness direction of the blade 27, a hard coating 33 is formed by the PVD or the CVD, and this hard coating 33 is made of the ceramics or the carbon material. Note that the hard coating 33 may be formed on substantially an entire surface of the blade 27 including the blade edge portion 27b on the other side in the blade thickness direction of the blade 27.

In a similar way to the double-edged kitchen knife 1 according to the first embodiment of the present disclosure, on a base of the hard coating 33 on the blade edge portion 27b on the other side in the blade thickness direction of the blade 27, a rough surface (fine irregular surface) 35 is formed by the grinding processing or the shot blast processing. Moreover, a maximum height (Rz) of surface roughness of the rough surface 35 is set to 10 to 30 μm.

A blade angle (angle on edge E side) μ2 of the blade 27 is set to 10 to 20 degrees, or 10 to 15 degrees, and a blade edge portion 27a on one side in the blade thickness direction of the blade 27 is subjected to the edging processing.

Note that the blade 27 is finished by a finishing method similar to the blade finishing method according to the second embodiment of the present disclosure.

Subsequently, a description is made of functions and effects of the third embodiment of the present disclosure.

The hard coating 33 is formed on the blade edge portion 27b on the other side in the blade thickness direction of the blade 27, and accordingly, mechanical strength (hardness) of the blade edge E of the single-edged kitchen knife 25 can be enhanced. Moreover, the PVD or the CVD is used as a forming method of the hard coating 33, and accordingly, such hard coatings 33 can be formed on a large number of the blades 27 at one time by the batch processing.

The hard coating 33 is formed by the PVD or the CVD on the blade edge portion 27b on the other side in the blade thickness direction of the blade 27, and thereafter, the rough surface 35 is formed on the base of the hard coating 33 on the blade edge portion 27b on the other side in the blade thickness direction of the blade 27, and the maximum height (Rz) of the surface roughness of the rough surface 35 is set to 10 to 30 μm. Accordingly, when the above-mentioned novel knowledge is applied, then as shown in FIG. 5B, the blade edge E of the single-edged kitchen knife 25 can be allowed to exhibit the saw tooth-like irregular line (line with irregularities).

Hence, also in the third embodiment of the present disclosure, similar effects to those of the first embodiment of the present disclosure are exerted.

Note that the present disclosure is not limited to the above descriptions of the embodiments, and is capable of being embodied in a variety of aspects as follows. For example, the technical idea applied to the double-edged kitchen knife 1 and the single-edged kitchen knife 25 may be applied to a double-edged knife (not shown) and a single-edged knife (not shown). Moreover, for example, hard particles with a diameter of 10 to 70 μm are blasted and embedded into the blade edge portion 3b on the other side in the blade thickness direction of the blade 3, whereby a hard coating (not shown) may be formed. Then, the scope of rights incorporated in the present disclosure is not limited to the above-mentioned embodiments.

What is claimed is:

1. A knife comprising:
a blade, wherein a cutting blade is formed on a blade edge portion at least on one side in a blade thickness direction; and
a handle provided on the blade,
wherein a hard coating is formed by PVD or CVD on a blade edge portion at least on other side in the blade thickness direction of the blade, a rough surface is formed on a base of the hard coating in the blade edge portion on the other side in the blade thickness direction of the blade, and a maximum height of surface roughness of the rough surface is set to 10 to 30 μm.

2. The knife according to claim 1, wherein the blade edge portion on the one side in the blade thickness direction of the blade is subjected to edging processing.

3. The knife according to claim 2, wherein the hard coating is removed by the edging processing from the blade edge portion on the one side in the blade thickness direction of the blade.

4. The knife according to claim 1, wherein the hard coating is made of ceramics or a carbon material.

5. A blade finishing method for finishing a blade, the blade being used for a knife and having a cutting blade formed on a blade edge portion at least on one side in a blade thickness direction, the blade finishing method comprising the steps of:
a rough surface forming step of forming a rough surface, wherein a maximum height of surface roughness is set to 10 to 30 μm, on a blade edge portion at least on other side in the blade thickness direction of the blade; and
a coating forming step, subsequent to the rough surface forming step, of forming a hard coating by PVD or CVD on the blade edge portion at least on the other side in the blade thickness direction of the blade so as to cover the rough surface.

6. The blade finishing method according to claim 5, wherein the rough surface forming step forms the rough surface on the blade edge portion on the other side in the blade thickness direction of the blade by performing grinding processing or shot blast processing for the blade edge portion on the other side in the blade thickness direction of the blade.

7. The blade finishing method according to claim 6, further comprising an edging step of performing edging processing for the blade edge portion on the one side in the blade thickness direction of the blade after the coating forming step is ended.
